(19) United States
(12) Patent Application Publication
(10) Pub. No.: US 2020/0260580 A1
(43) Pub. Date: Aug. 13, 2020

(54) PRINTED CIRCUIT BOARD

(71) Applicant: Samsung Electro-Mechanics Co., Ltd., Suwon-si (KR)

(72) Inventors: Young-Kuk KO, Suwon-si (KR); Yoong OH, Suwon-si (KR); Sang-Hoon KIM, Suwon-si (KR); Gyu-Mook KIM, Suwon-si (KR); Hea-Sung KIM, Suwon-si (KR)

(73) Assignee: Samsung Electro-Mechanics Co., Ltd., Suwon-si (KR)

(21) Appl. No.: 16/662,529

(22) Filed: Oct. 24, 2019

(30) Foreign Application Priority Data
Feb. 11, 2019 (KR) 10-2019-0015490

(51) Int. Cl. H05K 1/11; H05K 1/18

(52) U.S. Cl. CPC H05K 1/113; H05K 3/4682; H05K 1/181

(57) ABSTRACT

A printed circuit board includes: an insulating layer; a via passing through the insulating layer; and a metal post in contact with a surface of the via, and protruding from the insulating layer. The metal post includes a region having a width that is greater than a width of the via.

### CROSS-REFERENCE TO RELATED APPLICATIONS

This application claims the benefit under 35 U.S.C. § 119(a) of Korean Patent Application No. 10-2019-0015490 filed on Feb. 11, 2019 in the Korean Intellectual Property Office, the entire disclosure of which is incorporated herein by reference for all purposes.

### BACKGROUND

### 1. Field

The following description relates to a printed circuit board.

### 2. Description of Related Art

Along with the continued growth of the smartphone market, a technology for improving the performance of and reducing the thickness of a printed circuit board (PCB) is in demand. Product development for a radio frequency printed circuit board (RFPCB) is being conducted for thinning, miniaturization, and fine-scaling compared to existing products.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a printed circuit board includes: an insulating layer; a via passing through the insulating layer; and a metal post in contact with a surface of the via, and protruding from the insulating layer. The metal post includes a region having a width that is greater than a width of the via.

A first surface of the metal post may be in contact with the surface of the via. The first surface of the metal post may have a width that is greater than a width of the surface of the via.

An electroless plating layer may be disposed on a second surface of the metal post that is out of contact with the via.

A metal layer having a thickness that is less than a thickness of the metal post may be disposed on a second surface of the metal post that is out of contact with the via.

A side surface of the metal post may be inclined.

A cross-sectional area of the metal post may increase in a direction toward the via.

A cross-sectional area of the via may increase in a direction away from the metal post.

The metal post may protrude from a first surface of the insulating layer. The printed circuit board may further include at least one additional insulating layer disposed on a second surface of the insulating layer.

The printed circuit board may further include a solder resist layer disposed on an outermost layer of the at least one additional insulating layer.

The insulating layer may contain a non-photosensitive resin. The solder resist layer may contain a photosensitive resin.

In another general aspect, a printed circuit board includes: insulating layers that are vertically stacked; a first protective layer disposed on an outermost insulating layer among the insulating layers; a second protective layer disposed on another outermost insulating layer among the insulating layers, and formed of a material that is different from a material of the first protective layer; a via passing through the first protective layer; and a metal post in contact with the via, and protruding from the first protective layer.

The metal post may include a region having a width that is greater than a width of the via.

A first surface of the metal post may be in contact with a surface of the via. The first surface of the metal post may have a width that is greater than a width of the surface of the via.

An electroless plating layer may be formed on a second surface of the metal post that is out of contact with the via.

A metal layer having a thickness that is less than a thickness of the metal post may be disposed on a second surface of the metal post that is out of contact with the via.

A side surface of the metal post may be inclined.

A cross-sectional area of the metal post may increase in a direction toward the via.

A cross-sectional area of the via may increase in a direction away from the metal post.

The first protective layer may contain a non-photosensitive resin. The second protective layer may contain a photosensitive resin.

Other features and aspects will be apparent from the following detailed description, the drawings, and the claims.

### BRIEF DESCRIPTION OF THE DRAWINGS

FIG. 1 is a diagram showing a printed circuit board, according to an embodiment.

FIG. 2 is a diagram showing a printed circuit board, according to an embodiment.

FIG. 3 is a diagram showing a printed circuit board, according an embodiment.

FIGS. 4 to 8 are diagrams showing a method of manufacturing a printed circuit board, according to an embodiment.

FIG. 9 is a diagram showing an electronic element mounted on a printed circuit board, according to an embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

FIG. 1 is a diagram showing a printed circuit board (PCB) 10, according to an embodiment.

Referring to FIG. 1, the PCB 10 may include an insulating layer 100, a via 200, and a metal post 300.

The insulating layer 100 may contain a resin, and the resin of the insulating layer 100 may be selected from among thermosetting resins, thermoplastic resins, and the like. The insulating layer 100 may contain a non-photosensitive resin. For example, the resin of the insulating layer 100 may include an epoxy resin, polyimide, and the like, but the disclosure is not limited to these examples. A naphthalene type epoxy resin, a bisphenol A type epoxy resin, a bisphenol F type epoxy resin, a novolac type epoxy resin, a cresol novolac type epoxy resin, a rubber-modified epoxy resin, a cyclic aliphatic type epoxy resin, a silicon-based epoxy resin, a nitrogen-based epoxy resin, a phosphorus-based epoxy resin, or the like may be used as the epoxy resin, but the disclosure is not limited to these examples. For example, a prepreg (PPG) or an Ajinomoto build-up film (ABF) may be used as the insulating layer 100.

The insulating layer 100 may contain a fiber reinforcing material. The fiber reinforcing material contained in the insulating layer 100 may be glass cloth and may include a glass filament, a glass fiber, a glass fabric, or the like. The fiber reinforcing material may be located on a center surface of the insulating layer 100 and may be in the form of a twist fabric formed by weaving a plurality of fibers.

The insulating layer 100 may contain one or more inorganic fillers. Any one of silica (SiO₂), barium sulfate (BaSO₄), and alumina (Al₂O₃) may be used alone as an inorganic filler, or any two or more of SiO₂, BaSO₄, and Al₂O₃ may be used in combination as inorganic fillers.

The insulating layer 100 may have a first surface (e.g., upper surface) and a second surface (e.g., lower surface), and a circuit layer C1 (hereinafter, referred to as a first circuit layer) may be formed on the second surface of the insulating layer 100. The first circuit layer C1 transfers electric signals. The first circuit layer C1 may include at least one circuit line, and the circuit line may be formed of a metal such as copper, nickel, silver, gold, palladium, and aluminum.

The via 200 may pass through the insulating layer 100 in the thickness direction and may pass through both of the first surface and the second surface of the insulating layer 100. The via 200 may be electrically connected to the first circuit layer C1. For example, the via 200 may be brought into contact with the circuit line of the first circuit layer C1.

The via 200 may have a cross-sectional area increasing in a direction from one surface of the via 200 to another surface of the via 200. For example, in FIG. 1, the cross-sectional area of the via 200 may increase in a direction from a first surface (e.g., upper surface) of the via 200 to a second surface (e.g., lower surface) of the via 200. In this example, the via 200 may have a regular trapezoid-shaped longitudinal section. In accordance with the foregoing description, the cross-sectional area of the via 200 may increase in a direction away from the metal post 300.

The via 200 may be formed of a metal. The metal of the via 200 may be selected from among copper, nickel, silver, gold, palladium, and aluminum, but the disclosure is not limited to these examples.

The metal post 300 may be formed on the first surface (the upper surface) of the via 200 and may protrude from the insulating layer 100. For example, the metal post 300 may protrude from the first surface of the insulating layer 100.

As shown in FIG. 9, the metal post 300 may provide a portion for mounting an electronic element E. The electronic element E may be coupled to the metal post 300 through a low melting point metal member LM, and may have a terminal T coupled to the metal post 300 by the low melting point metal member LM. Since the metal post 300 protrudes from the insulating layer 100, an implementation can be provided with a fine pitch compared to a conventional configuration in which the electronic element E is mounted on a pad under a solder resist using the low melting point metal member LM.

As shown in FIG. 1, the metal post 300 may include a region having a width that is greater than a width of the via 200. For example, the metal post 300 may have a first surface (e.g., lower surface) in contact with the first surface (e.g., upper surface) of the via 200, and the first surface of the metal post 300 may have a width that is greater than a width of the first surface of the via 200. That is, in a flat surface including a bonding surface between the metal post 300 and the via 200, the metal post 300 may have a width that is greater than a width of the via 200. Also, the overall region of the metal post 300 may have a width that is greater than a width of the overall region of the via 200. The width of the metal post 300 may be constant in a vertical direction of the metal post 300. The above-described “width” in this paragraph may be replaced with “cross-sectional area.”

When the width (or the cross-sectional area) of the metal post 300 is greater than the width (or the cross-sectional area) of the via 200 and the low melting point metal member LM is formed on the metal post 300, the area in which the low melting point metal member LM is formed increases, and thus it is possible to improve the mounting reliability of the electronic element E. Also, in this example, the first surface (e.g., the lower surface) of the metal post 300 may be in contact with the first surface (e.g., the upper surface) of the insulating layer 100.

When a plurality of metal posts 300 are provided, the metal posts 300 may have substantially the same height and may have second surfaces (e.g., upper surfaces) formed coplanar with each other. That is, the metal posts 300 may have no deviation in height.

The metal post 300 may have a thickness that is greater than a thickness of the via 200. However, the disclosure is not limited to this example. As shown in FIG. 1, the metal post 300 may have a thickness that is less than a thickness of the via 200. In contrast to the example illustrated in FIG. 1, the metal post 300 and the via 200 may have a same thickness.

The metal post 300 may be formed of a metal, and the metal of the metal post 300 may be selected from among copper, nickel, silver, gold, palladium, and aluminum. However, the disclosure is not limited to the foregoing examples.

The PCB 10 embodiment may further include an additional insulating layer 110, an additional circuit layer, a solder resist layer 500, and other layers, depending on an application.

The additional insulating layer 110 is stacked on the second surface (e.g., the lower surface) of the insulating layer 100 and includes at least one layer. The insulating layer 100 may be formed of the same material as the additional insulating layer 110.

The additional circuit layer may be formed on the additional insulating layer 110. The additional circuit layer may include at least one circuit line.

In FIG. 1, two additional insulating layers 110 are shown. A second circuit layer C2 and a third circuit layer C3 may be formed on the additional insulating layers, respectively. Although not shown in FIG. 1, the number of additional insulating layers 110 may be three or more. In this case, a fourth circuit layer and the like may be further formed.

The first circuit layer C1, the second circuit layer C2, and the third circuit layer C3 may be electrically connected to each other through an inner via V.

The solder resist layer 500 is a layer for covering and protecting an outermost circuit layer (e.g., the third circuit layer C3 in FIG. 1). An opening may be formed in the solder resist layer 500 to expose a portion of the outermost circuit layer (e.g., the third circuit layer C3). The portion of the outermost circuit layer (e.g., the third circuit layer C3) exposed by the solder resist layer 500 may be configured as a pad, and may be connected to an external board or an external device.

The solder resist layer 500 may contain a photosensitive material. For example, the solder resist layer 500 may contain a photocurable resin. In this case, the opening of the solder resist layer 500 may be formed through a photolithography process.

As described above, the PCB 10 may include a plurality of additional insulating layers 110, the insulating layer 100, the solder resist layer 500, the via 200, and the metal post 300.

The insulating layers 110 may be vertically stacked. Each insulating layer 110 may contain a resin, and the resin of each insulating layer 110 may be selected from among thermosetting resins, thermoplastic resins, and the like. For example, the resin of each insulating layer 110 may include an epoxy resin, polyimide, and the like, but the disclosure is not limited to these examples. A naphthalene type epoxy resin, a bisphenol A type epoxy resin, a bisphenol F type epoxy resin, a novolac type epoxy resin, a cresol novolac type epoxy resin, a rubber-modified epoxy resin, a cyclic aliphatic type epoxy resin, a silicon-based epoxy resin, a nitrogen-based epoxy resin, a phosphorus-based epoxy resin, or the like may be used as the epoxy resin, but the disclosure is not limited to these examples. For example, a PPG or an ABF may be used as the insulating layer 110.

The insulating layer 110 may contain a fiber reinforcing material. The fiber reinforcing material contained in the insulating layer 110 may be glass cloth and may include a glass filament, a glass fiber, a glass fabric, or the like. The fiber reinforcing material may be located on the center surface of the insulating layer 110 and may be in the form of a twist fabric formed by weaving a plurality of fibers.

The insulating layer 110 may contain inorganic fillers. Any one of silica (SiO₂), barium sulfate (BaSO₄), and alumina (Al₂O₃) may be used alone as an inorganic filler, or any two or more of SiO₂, BaSO₄, and Al₂O₃ may be used in combination as inorganic fillers.

A circuit layer may be formed in each insulating layer 110. That is, a circuit layer is formed on one surface of each insulating layer 110, and the circuit layer may be buried in each insulating layer 110. In FIG. 1, in an example in which there are two additional insulating layers 110, the circuit layer may include three layers (a first circuit layer C1, a second circuit layer C2, and a third circuit layer C3). Each circuit layer may include at least one circuit line. The circuit line may be formed of a metal such as copper, nickel, silver, gold, palladium, aluminum, and the like.

The insulating layer 100 may be stacked on an outermost additional insulating layer 110 among the additional insulating layers 110 (e.g., an uppermost additional insulating layer 110) and may protect a circuit layer formed in the outermost additional insulating layer 110 (the first circuit layer C1). Thus, the insulating layer 100 forms a first protective layer, and will be referred to as “the first protective layer 100” going forward. The first protective layer 100 may contain no photosensitive (photocurable) resin. The first protective layer 100 may contain a non-photosensitive resin. The first protective layer 100 may contain a thermosetting resin. For example, the first protective layer 100 may contain an epoxy resin. The first protective layer 100 may be formed of the same material as that of the additional insulating layers 110.

The solder resist layer 500 may be stacked on another outermost additional insulating layer among the additional insulating layers 110 (e.g., a lowermost additional insulating layer 110) and may protect a circuit layer formed on the other outermost additional insulating layer 110 (the third circuit layer C3 in FIG. 1). Thus, the solder resist layer 500 forms a second protective layer, and will be referred to as “the second protective layer 500” going forward. The second protective layer 500 may be formed of a different material than that of the first protective layer 100. The second protective layer 500 may contain a photosensitive resin and also may contain a photocurable resin. The second protective layer 500 may include a solder resist.

Since the first protective layer 100 and the second protective layer 500 are formed of different materials, it is possible to implement an asymmetric PCB.

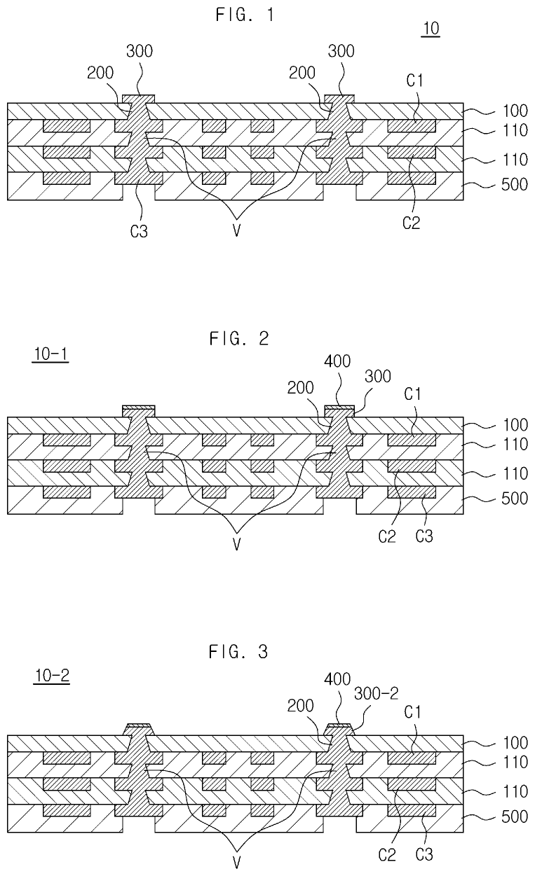

FIG. 2 is a diagram showing a PCB 10-1, according to an embodiment.

Referring to FIG. 2, the PCB 10-1 is similar to the PCB 10 of FIG. 1, but, in comparison to the PCB 10, further includes a metal layer 400.

The metal layer 400 is formed on the second surface (e.g., the upper surface) of the metal post 300, which is not in contact with a via 200. The metal layer 400 may be an electroless plating layer. The metal layer 400 may have a thickness that is less than the thickness of the metal post 300. The metal layer 400 may be formed of a metal that is the same as or different from the metal of the metal post 300. The metal layer 400 may have a multi-layered structure. In this example, the metal layer 400 may have a multi-layered structure composed of different metals.

FIG. 3 is a diagram showing a PCB 10-2, according to an embodiment.

Referring to FIG. 3, the PCB 10-2 is similar to the PCB 10-1, but may have a metal post 300-2 having a side surface that is inclined. The inclined side surface of the metal post 300-2 will be described below. In the following description, the parts that have been described in the embodiments of FIGS. 1 and 2 will not be described again.

The inclined side surface of the metal post 300-2 may be a downward inclined surface. That is, the inclined side surface of the metal post 300-2 may be inclined such that a width (a cross-sectional area) of the metal post 300-2 increases in a direction toward the via 200. Like the via 200, the metal post 300-2 may have a regular trapezoid-shaped longitudinal section.

The width of a first, or lower, surface of the metal post 300-2 (the width of a surface in contact with the via 200) may be greater than the width of the first, or upper, surface of the via 200 (the width of a surface in contact with the metal post 300-2). Also, the width of a second, or upper, surface of the metal post 300-2 (the width of a surface not in contact with the via 200) may also be greater than the width of the first, or upper, surface of the via 200 (the width of the surface in contact with the metal post 300-2).

When a metal layer 400 is formed on the second, or upper, surface of the metal post 300-2 (the surface not in contact with the via 200), a side surface of the metal layer 400 may also be inclined. The inclined side surface of the metal layer 400 may have the same slope as the inclined side surface of the metal post 300-2.

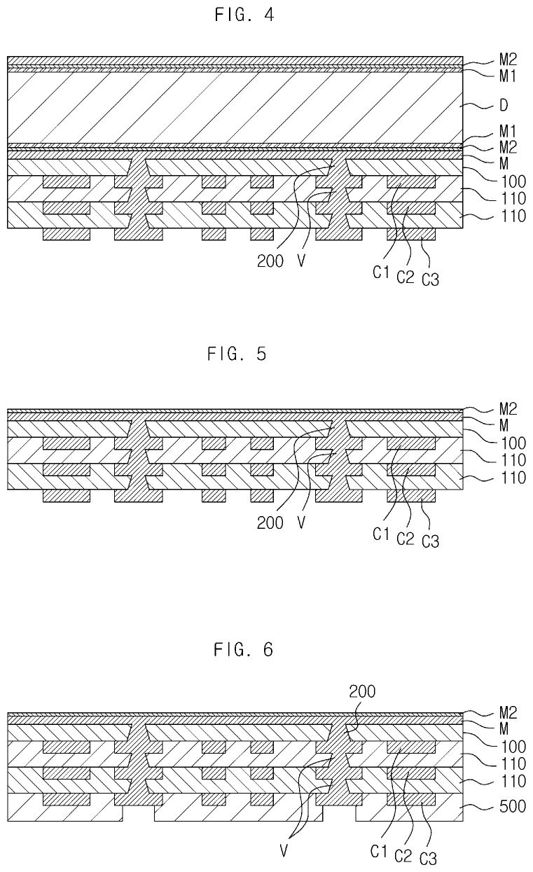

FIGS. 4 to 8 are diagrams showing a method of manufacturing the PCB 10-1, according to an embodiment. FIG. 9 is a diagram showing the electronic element E mounted on the PCB 10-1, according to an embodiment.

Referring to FIG. 4, a metal plating layer M is formed on two opposite sides of a detachable carrier D, and the insulating layer 100 is formed. The insulating layer 100 is stacked on the metal plating layer M. Also, the via 200 and the first circuit layer C1 may be formed in/on the insulating layer 100.

A first metal foil M1 and a second metal foil M2 may be provided on the two opposite sides of the detachable carrier D, and the metal plating layer M may be grown through electrolytic plating using the second metal foil M2 as a seed layer. That is, the metal plating layer M is formed in contact with the second metal foil M2. The first metal foil M1 may have a thickness that is greater than a thickness of the second metal foil M2, but the disclosure is not limited to such an example. The first metal foil M1 and the second metal foil M2 may each be a copper foil.

A via hole is formed in the insulating layer 100, and the inside of the via hole may be plated to form the via 200. The first circuit layer C1 may be formed on a surface of the insulating layer 100 not in contact with the metal plating layer M and may be formed simultaneously with the via 200. The via 200 is electrically connected to the first circuit layer C1 and is in contact with a circuit line of the first circuit layer C1.

After the insulating layer 100, the via 200, and the first circuit layer C1 are formed, the additional insulating layers 110 and the additional circuit layers (e.g., the second circuit layer C2 and the third circuit layer C3) may also be further.

Referring to FIG. 4, the metal plating layer M is formed on both sides of a detachable carrier D, and the insulating layer 100 forms a first protective layer, and may therefore be referred to as “the first protective layer 100.” The first protective layer 100 is stacked on the metal plating layer M.

In FIG. 4, only layers formed on one surface among the opposite surfaces of the detachable carrier D are shown, and layers formed on the other surface among the opposite surfaces of the detachable carrier D are omitted.

Referring to FIG. 5, the detachable carrier D is removed. For example, in removing the detachable carrier D, the first metal foil M1 and the second metal foil M2 are separated from each other, and the first metal foil M1 is removed while the second metal foil M2 remains attached to the first protective layer 100 and the additional insulating layers 110.

Referring to FIG. 6, the solder resist layer 500 is stacked on an outermost additional insulating layer 110 among the additional insulating layers 110. An opening may be formed in the solder resist layer 500 to expose a portion of a third circuit layer C3, which is an outermost circuit layer.

Thus, the solder resist layer 500 forms a second protective layer, and may therefore be referred to as “the second protective layer 500.” The second protective layer 500 may be formed of a material that is different from the material of the first protective layer 100. For example, the first protective layer 100 may be formed of a thermosetting resin, and the second protective layer 500 may be formed of a photocurable resin.

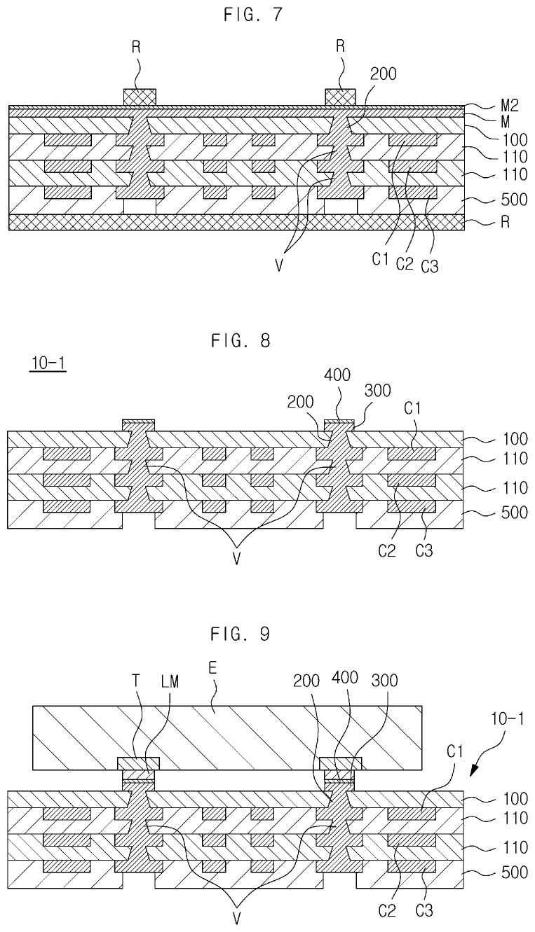

Referring to FIG. 7, a resist R is formed on both surfaces of the laminate formed as illustrated in FIGS. 4 to 6. The resist R may be formed of a photosensitive material. The resist R may be formed on one surface of the laminate (a surface at which the second metal foil M2 is formed) to correspond to a region in which the metal post 300 is to be formed. Also, the resist R covers the entire other surface of the laminate.

Referring to FIG. 8, the metal post 300 is completed. The remaining region other than the region where the resist R is formed may be etched to pattern the metal plating layer M, and thus the metal post 300 may be formed. The second metal foil M2 located on the metal plating layer M may be etched together with the metal plating layer M to form the metal layer 400 on the metal post 300.

When the metal plating layer M and the second metal foil M2 are patterned through etching, side surfaces of the metal post 300 and the metal layer 400 may each include a downward inclined surface, as shown in the embodiment of FIG. 3.

Referring to FIG. 9, the electronic element E may be mounted on the metal post 300. The electronic element E may be an active element, a passive element, an integrated circuit, or the like. The terminal T is formed in the electronic element E, and the terminal T may be coupled to the metal post 300, and thus a circuit layer (e.g., the first circuit layer C1) of the PCB 10-1 and the electronic element E may be electrically connected to each other. The terminal T of the electronic element E and the metal post 300 may be coupled to each other using the low melting point metal member LM, and the low melting point metal member LM may be a solder including tin, lead, and the like.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

1. A printed circuit board, comprising:
an insulating layer;
a via passing through the insulating layer;
a metal post protruding from the insulating layer and comprising a first surface in contact with a surface of the via, a second surface opposing the first surface, and a side surface separating the first surface and the second surface; and
a metal layer disposed on the second surface of the metal post,
wherein the metal layer is disposed on the second surface of the metal post from the side surface to a center of the second surface.

2. The printed circuit board of claim 1, wherein the first surface of the metal post has a width that is greater than a width of the surface of the via.

3. The printed circuit board of claim 1, wherein the metal layer is an electroless plating layer.

4. The printed circuit board of claim 1, wherein a thickness of the metal layer is less than a thickness of the metal post.

5. The printed circuit board of claim 1, wherein the side surface of the metal post is inclined.

6. The printed circuit board of claim 1, wherein a cross-sectional area of the metal post increases in a direction toward the via.

7. The printed circuit board of claim 1, wherein a cross-sectional area of the via increases in a direction away from the metal post.

8. The printed circuit board of claim 1, wherein the metal post protrudes from a first surface of the insulating layer, and
wherein the printed circuit board further comprises at least one additional insulating layer disposed on a second surface of the insulating layer.

9. The printed circuit board of claim 8, further comprising a solder resist layer disposed on an outermost layer of the at least one additional insulating layer.

10. The printed circuit board of claim 9, wherein the insulating layer contains a non-photosensitive resin, and the solder resist layer contains a photosensitive resin.

11. A printed circuit board, comprising:
insulating layers that are vertically stacked;
a first protective layer disposed on an outermost insulating layer among the insulating layers;
a second protective layer disposed on another outermost insulating layer among the insulating layers, and formed of a material that is different from a material of the first protective layer;
a via passing through the first protective layer; and
a metal post protruding from the first protective layer and comprising a first surface in contact with a surface of the via, a second surface opposing the first surface, and a side surface separating the first surface and the second surface, and
a metal layer disposed on the second surface of the metal post,
wherein the metal layer is disposed on the second surface of the metal post from the side surface to a center of the second surface.

12. The printed circuit board of claim 11, wherein the metal post includes a region having a width that is greater than a width of the via.

13. The printed circuit board of claim 11, wherein the first surface of the metal post has a width that is greater than a width of the surface of the via.

14. The printed circuit board of claim 11, wherein the metal layer is an electroless plating layer.

15. The printed circuit board of claim 11, wherein a thickness of the metal layer is less than a thickness of the metal post.

16. The printed circuit board of claim 11, wherein the side surface of the metal post is inclined.

17. The printed circuit board of claim 11, wherein a cross-sectional area of the metal post increases in a direction toward the via.

18. The printed circuit board of claim 11, wherein a cross-sectional area of the via increases in a direction away from the metal post.

19. The printed circuit board of claim 11, wherein the first protective layer contains a non-photosensitive resin, and the second protective layer contains a photosensitive resin.

20. The printed circuit board of claim 1, wherein the metal post comprises a region having a width that is greater than a width of the via.
